(19) United States
(12) Patent Application Publication
(10) Pub. No.: US 2025/0385208 A1
(43) Pub. Date: Dec. 18, 2025

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventors: Youngjun PARK, Suwon-si (KR); Yoonha JUNG, Suwon-si (KR); Sunghawn BAE, Suwon-si (KR)

(21) Appl. No.: 19/008,827

(22) Filed: Jan. 3, 2025

(30) Foreign Application Priority Data
Jun. 14, 2024 (KR) 10-2024-0077805

(51) Int. Cl. H01L 23/00

(52) U.S. Cl. CPC H01L 24/14; H01L 24/13; H01L 24/16; H01L 2224/13078; H01L 2224/1403; H01L 2224/14051; H01L 2224/14132; H01L 2224/14515; H01L 2224/16227

(57) ABSTRACT

A semiconductor package includes an upper part structure, a lower part structure, and a first connecting body electrically connecting the upper part structure to the lower part structure. The first connecting body includes a first pad disposed on a front side of the upper part structure. A plurality of first bumps is disposed on the first pad. The plurality of first bumps are electrically connected to each other via the first pad. The plurality of first bumps are spaced radially apart from a central area of the first pad.

### CROSS-REFERENCE TO RELATED APPLICATION(S)

This application claims priority under 35 U.S.C. § 119 to Korean Patent Application No. 10-2024-0077805, filed on Jun. 14, 2024 in the Korean Intellectual Property Office, the disclosure of which is incorporated by reference in its entirety herein.

### 1. TECHNICAL FIELD

Embodiments relate to a semiconductor package and a method of manufacturing the semiconductor package.

### 2. DISCUSSION OF RELATED ART

The demand for high-performance, high-speed, and miniaturized electronic components is increasing, and the integration level of semiconductor chips is increasing along with the advancement of the electronics industry. Research is being conducted concerning a semiconductor chip with fine patterns to provide an increased level of integration of the semiconductor chips, and a semiconductor package including such semiconductor chips. To increase the level of integration of semiconductor chips, research is being conducted with respect to the layout of semiconductor chips and/or bumps that electrically connect the semiconductor chips and the package substrate.

### SUMMARY

An aspect provides a semiconductor package that efficiently inspects defects in a semiconductor chip or a semiconductor package containing a semiconductor chip, and a method of manufacturing the semiconductor package.

Another aspect also provides a semiconductor package that secures flexibility in bump layout, and a method of manufacturing the semiconductor package.

The technical tasks to be achieved by the present embodiments are not limited to the technical tasks described above, and other technical tasks may be inferred from the following embodiments by those skilled in the art.

According to an embodiment of the present disclosure, a semiconductor package includes an upper part structure, a lower part structure, and a first connecting body electrically connecting the upper part structure to the lower part structure. The first connecting body includes a first pad disposed on a front side of the upper part structure. A plurality of first bumps is disposed on the first pad. The plurality of first bumps are electrically connected to each other via the first pad. The plurality of first bumps are spaced radially apart from a central area of the first pad.

According to an embodiment of the present disclosure, a semiconductor package includes a semiconductor device and a connecting body that is disposed on a side of the semiconductor device. The connecting body includes a center pad electrically connected to the semiconductor device. A plurality of edge pads is electrically connected to the semiconductor device and the center pad. The plurality of edge pads is spaced apart from each other and surround the center pad. A plurality of bumps is disposed on the plurality of edge pads. The center pad has one side that is exposed to an outside of the semiconductor device.

According to an embodiment of the present disclosure, a semiconductor package includes an interposer structure including a through via disposed inside the interposer structure. A semiconductor chip is disposed on the interposer structure. A first connecting body and a second connecting body are disposed on a front side of the semiconductor chip facing the interposer structure. The first connection body and the second connecting body electrically connect the semiconductor chip and the interposer structure to each other. The first connecting body comprises a first pad disposed inside the semiconductor chip and electrically connected to distribution lines that transmit power signals of the semiconductor chip. A power bump is disposed on the front side of the semiconductor chip. The power bump is electrically connected to the first pad. The second connecting body comprises a second pad disposed inside the semiconductor chip and electrically connected to distribution lines transmitting data signals of the semiconductor chip. A signal bump is disposed on the front side of the semiconductor chip. The signal bump is electrically connected to the second pad. The semiconductor chip includes a first area and a second area surrounding the first area. The power bump is disposed on the first area and the signal bump is disposed on the second area. A plurality of power bumps is disposed on the first pad. The signal bump is disposed on the second pad.

Additional aspects of embodiments will be set forth in part in the description which follows and, in part, will be apparent from the description, or may be learned by practice of the disclosure.

According to embodiments, it is possible to minimize the risk of damage to bumps that may occur during the process of inspecting defects in a semiconductor chip or a semiconductor package including semiconductor chips.

According to embodiments, it is possible to secure flexibility in bump design.

Further, according to embodiments, it is possible to simplify the bump formation process.

The effects achievable by embodiments of the present disclosure are not limited to the effect mentioned above, and other effects not mentioned will be clearly understood by those of ordinary skill in the art to which the present disclosure pertains from the following description.

### BRIEF DESCRIPTION OF THE DRAWINGS

These and/or other aspects, features, and advantages of the present disclosure will become apparent and more readily appreciated from the following description of non-limiting embodiments, taken in conjunction with the accompanying drawings of which:

FIG. 1 is a layout drawing of a semiconductor package according to an embodiment of the present disclosure;

FIG. 2 is a cross-sectional view schematically illustrating a shape cut along the line I-I of FIG. 1 according to an embodiment of the present disclosure;

FIG. 3 is a drawing schematically illustrating a first semiconductor chip of FIG. 2 as viewed from a front side according to an embodiment of the present disclosure;

FIG. 4 is a drawing schematically illustrating an enlarged view of a part A of FIG. 2 according to an embodiment of the present disclosure;

FIG. 5 is a drawing schematically illustrating an enlarged view of a part B of FIG. 3 according to an embodiment of the present disclosure;

FIG. 6 is a drawing schematically illustrating an enlarged view of a part C of FIG. 2 according to an embodiment of the present disclosure;

FIGS. 7A to 7C are drawings schematically illustrating a first connecting body seen from the front side according to embodiments of the present disclosure;

FIG. 8 is a flowchart illustrating a method for manufacturing a semiconductor package according to an embodiment of the present disclosure;

FIGS. 9 to 17 are drawings of intermediate operations for explaining a method for manufacturing a semiconductor package according to embodiments of the present disclosure; and

FIG. 18 is a drawing schematically illustrating a semiconductor package according to an embodiment of the present disclosure.

### DETAILED DESCRIPTION OF EMBODIMENTS

Embodiments of the present disclosure described below can be modified and implemented in various forms. The technical idea of embodiments of the present disclosure are not limited to embodiments described below. With regard to the terms used in the described embodiments of the present disclosure, except for the cases where the applicant arbitrarily selected and described in detail the meaning thereof in the present disclosure, the currently widely used general terms are selected as much as possible while taking into account the function in the present disclosure. However, terms may vary depending on the intention of a person skilled in the art to which the present disclosure pertains, case law, or the emergence of new technologies. Further, terms and words used in the present disclosure and claims should not be construed as limited to their ordinary or dictionary meanings, and the terms and words should be interpreted to include meanings and concepts consistent with the technical idea of the present disclosure.

It will be understood that, when an element (for example, a first element) is “(operatively or communicatively) coupled with/to” or “connected to” another element (for example, a second element), the element may be directly coupled with/to another element, or there may be an intervening element (for example, a third element) interposed between the element and another element. When an element is directly coupled with/to or directly connected to another element, no intervening elements may be present. The terms “have,” “may have,” “include,” and “may include” as used herein indicate the presence of corresponding features (for example, elements such as numerical values, functions, operations, or parts), and do not preclude the presence of additional features.

In the present disclosure, singular expressions include plural expressions unless the context clearly indicates otherwise. Further, terms “first,” “second” and so on may be used to describe various components. However, the components are not necessarily limited by the terms, and the terms may be used for the purpose of distinguishing one component from another. Within the scope of the technical idea of embodiments of the present disclosure, the first component may be named as the second component. Similarly, the second component may also be named the first component. Further, the shape and size of components may be exaggerated to emphasize clear explanation.

Hereinafter, non-limiting embodiments of the present disclosure are described in detail with reference to the attached drawings.

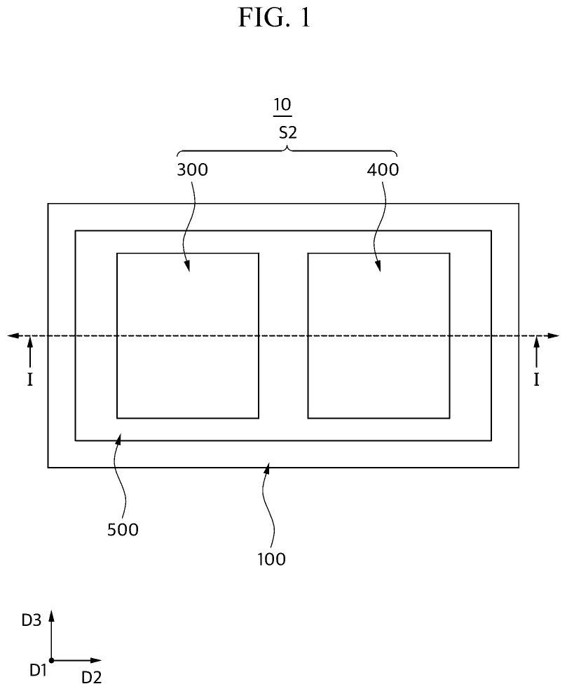

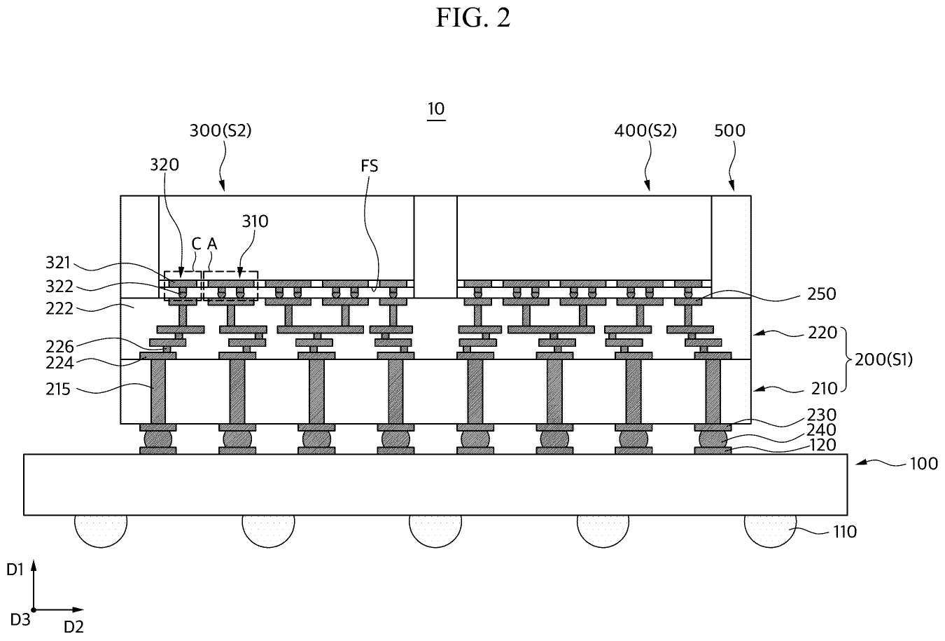

FIG. 1 is a layout drawing of a semiconductor package according to an embodiment. FIG. 2 is a cross-sectional view schematically illustrating a shape cut along the line I-I of FIG. 1.

Referring to FIGS. 1 and 2, a semiconductor package 10 may include a package substrate 100, a lower part structure S1 and an upper part structure S2.

In some embodiments, the lower part structure S1 and the upper part structure S2 may be semiconductor devices. For example, in an embodiment the lower part structure S1 and the upper part structure S2 may include at least one of a semiconductor chip, an interposer that connects different conductors and transmits signals, a package substrate, a redistribution substrate manufactured through the redistribution process and a printed circuit board (PCB). Hereinafter, to help understanding, described are embodiments in which the lower part structure S1 is an interposer structure 200 which includes an interposer 210, and the upper part structure S2 includes at least one semiconductor chip (e.g., a first semiconductor chip 300 and a second semiconductor chip 400). However, embodiments of the present disclosure are not necessarily limited thereto.

In some embodiments, the package substrate 100 may be a PCB or a ceramic substrate. Further, the package substrate 100 may be a distribution substrate for a wafer level package (WLP) manufactured at the wafer level. In an embodiment in which the package substrate 100 is a PCB, the package substrate 100 may include at least one material selected from tetrafunctional epoxy, polyphenylene ether, epoxy/polyphenylene oxide, bismaleimide triazine (BT), thermount, cyanate ester and liquid crystal polymer. Further, the package substrate 100 may include a resin impregnated in a core material such as glass fiber (glass cloth, glass fabric) together with an inorganic filler. For example, in an embodiment prepreg, an ajinomoto build-up film (ABF), FR-4 or bismaleimide triazine (BT) may be included. However, the package substrate 100 is not necessarily limited to what is described above, and various types of substrates may be included.

In some embodiments, the package substrate 100, the lower part structure S1 and the upper part structure S2 may be arranged in one direction. Hereinafter, when it is defined that the direction in which the lower part structure S1 and the upper part structure S2 are arranged is the first direction D1 and when the semiconductor is looked from a side, the direction perpendicular to the first direction D1 is the second direction D2. Further, it is defined that the direction perpendicular to the plane containing both the first direction D1 and the second direction D2 is the third direction D3. For example, the first direction D1 may be a direction perpendicular to the ground.

In some embodiments, the package substrate 100, the lower part structure S1, and the upper part structure S2 may be sequentially arranged along the first direction D1. For example, in some embodiments, the package substrate 100 may be disposed on the lower side of the interposer structure 200 (e.g., in a direction opposite to the first direction D1). Further, in some embodiments, at least one semiconductor chip (the first semiconductor chip 300 and the second semiconductor chip 400) may be disposed on the upper side of the interposer structure 200.

In some embodiments, a bottom side of the interposer structure 200 facing a front side of the package substrate 100 may be referred to as a front side of the interposer structure 200. Further, a front side of the interposer structure 200 facing a bottom side of the semiconductor chip (e.g., the first semiconductor chip 300 and the second semiconductor chip 400) may be referred to as a back side of the interposer structure 200. Similarly, a bottom side of the semiconductor chip (e.g., the first semiconductor chip 300 and the second semiconductor chip 400) facing the front side of the interposer structure 200 may be referred to as a front side FS of the semiconductor chip (e.g., the first semiconductor chip 300 and the second semiconductor chip 400).

In some embodiments, an external connection terminal 110 configured to be electrically connected to an external device may be disposed on (e.g., disposed directly thereon) the bottom side of the package substrate 100. The external connection terminal 110 may include a conductive material. In an embodiment, the external connection terminal 110 may have a spherical or oval shape. However, embodiments of the present disclosure are not necessarily limited thereto. In an embodiment, the external connection terminal 110 may be attached to an external connection pad and fixed on the bottom side of the package substrate 100. Further, in some embodiments, a first connection pad 120 may be disposed on the front side of the package substrate 100 (e.g., disposed directly thereon in the first direction D1). The first connection pad 120 may contain conductive material. In an embodiment, the first connection pad 120 may contain at least one of copper (Cu), aluminum (Al), tin (Sn), indium (In), lead (Pb), zinc (Zn), nickel (Ni), gold (Au), silver (Ag), antimony (Sb), bismuth (Bi), and combinations thereof. However, embodiments of the present disclosure are not necessarily limited thereto. The first connection pad 120 may be electrically connected to a connecting bump 240 described later. For example, in an embodiment the first connection pad 120 may be directly physically connected to the connecting bump 240. In an embodiment, each of the external connection terminal 110 and the first connection pad 120 may be electrically connected to a distribution circuit formed within the package substrate 100. The distribution circuit may be configured as a single layer or multiple layers within the package substrate 100. Accordingly, the package substrate 100 may be electrically connected to the interposer structure 200. As described below, the interposer structure 200 may be electrically connected to a semiconductor chip (e.g., the first semiconductor chip 300 and the second semiconductor chip 400). The semiconductor chip (e.g., the first semiconductor chip 300 and the second semiconductor chip 400) may exchange electrical signals with an external device through the interposer structure 200 and the package substrate 100.

In some embodiments, the interposer structure 200 may be mounted on the package substrate 100. The interposer structure 200 facilitates connection between the package substrate 100 and the semiconductor chip (e.g., the first semiconductor chip 300 and the second semiconductor chip 400) described below, and prevent warpage or distortion of the semiconductor package 10. In an embodiment, the interposer structure 200 may contain the interposer 210 and a redistribution layer 220. In some embodiments, the redistribution layer 220 may be disposed on top of the interposer 210 (e.g., disposed directly thereon in the first direction D1). However, embodiments of the present disclosure are not necessarily limited thereto and the arrangement of the redistribution layer 220 may vary. In an embodiment, an additional redistribution layer may also be disposed on a lower side of the interposer 210, and the redistribution layer may not be disposed on the upper and lower sides of the interposer 210. In some embodiments, the interposer 210 may be a silicon (Si) interposer. However, embodiments of the present disclosure are not necessarily limited thereto and the composition of the interposer 210 may vary. For example, in some embodiments the interposer 210 may be an organic interposer using organic substrates such as polyimide, bismaleimide triazine (BT) and FR-4, and the interposer 210 may be a glass interposer using a glass substrate.

In some embodiments, a second connection pad 230 may be disposed on a bottom side of the interposer 210 (e.g., disposed directly thereon in a direction opposite to the first direction D1). The second connection pad 230 may contain conductive material. For example, in an embodiment the second connection pad 230 may include at least one of copper (Cu), aluminum (Al), tin (Sn), indium (In), lead (Pb), zinc (Zn), nickel (Ni), gold (Au), silver (Ag), antimony (Sb), bismuth (Bi) and combinations thereof. However, embodiments of the present disclosure are not necessarily limited thereto.

In an embodiment, an interposer passivation layer may be further disposed on the bottom side of the interposer 210 to protect the internal structure of the interposer 210 from the external environment or external impact. For example, in an embodiment the interposer passivation layer may be formed by applying a material including a solder resist made of an organic material such as epoxy, acrylic, or polyimide to the outermost surface of the interposer 210. However, embodiments of the present disclosure are not necessarily limited thereto and the material of the solder resist may vary, such as depending on a type of the interposer 210. In an embodiment, the second connection pad 230 may be exposed from the interposer 210 through an opening formed in the interposer passivation layer.

In some embodiments, the connecting bump 240 is disposed between the first connection pad 120 and the second connection pad 230 (e.g., in the first direction D1). Further, the connecting bump 240 may be bonded to the first connection pad 120 and the second connection pad 230, and accordingly, the connecting bump 240 is electrically connected to the first connection pad 120 and the second connection pad 230. The connecting bump 240 may include a conductive material. For example, in an embodiment the connecting bump 240 may include at least one of copper (Cu), aluminum (Al), tin (Sn), indium (In), lead (Pb), zinc (Zn), nickel (Ni), gold (Au), silver (Ag), antimony (Sb), bismuth (Bi) and combinations thereof. However, embodiments of the present disclosure are not necessarily limited thereto. In some embodiments, the connecting bump 240 may be a solder bump or a solder ball. However, embodiments of the present disclosure are not necessarily limited thereto. For example, the connecting bump 240 may have various shapes such as land, ball, pin, pillar and so on. Further, the number, spacing and arrangement of connecting bumps 240 are not necessarily limited by what is illustrated, and the number, spacing and arrangement of the connecting bumps 240 may vary depending on the design.

In some embodiments, at least one through via 215 may be disposed within the interposer 210. In an embodiment, the through via 215 may be formed by forming a via hole within the interposer 210 and filling the via hole with a conductive material. For example, the through via 215 may be a through-silicon via (TSV). In an embodiment, the through via 215 may include at least one of copper (Cu), aluminum (Al), tin (Sn), indium (In), tungsten (W), lead (Pb), zinc (Zn), nickel (Ni), gold (Au), silver (Ag), antimony (Sb), bismuth (Bi), titanium (Ti) and combinations thereof. However, embodiments of the present disclosure are not necessarily limited thereto and the through via 215 may vary. The through via 215 may be arranged to penetrate vertically through the interposer 210 (e.g., in the first direction D1). For example, the through via 215 may be arranged to penetrate the front side and the bottom side of the interposer 210, respectively. FIG. 2 illustrates that the cross section of the through via 215 is rectangular. However, embodiments of the present disclosure are not necessarily limited thereto and the cross section of the through via 215 may be modified in various ways. For example, in some embodiments the through via 215 may have a tapered shape in which its width gradually decreases along the first direction D1 or increases along the first direction D1. The through via 215 may be electrically connected to the second connection pad 230.

In some embodiments, the redistribution layer 220 may include an insulating layer 222 and a redistribution line (e.g., a redistribution pattern 224 and a redistribution via 226). In an embodiment, the insulating layer 222 may include an organic material such as a photo imageable dielectric (PID) material and a photosensitive polyimide (PSPI) material. For example, in an embodiment the PID material may include at least one of PSPI, polybenzoxazole, phenol-based polymer, and benzocyclobutene-based polymer. However, embodiments of the present disclosure are not necessarily limited thereto. For example, in an embodiment, the insulating layer 222 may be formed of an inorganic dielectric material such as silicon nitride and silicon oxide.

In some embodiments, a redistribution passivation layer may be formed on the front side of the insulating layer 222. The redistribution passivation layer may protect the internal structure of the insulating layer 222 from the external environment or impact. The redistribution passivation layer may be composed of the same or similar material as the interposer passivation layer formed on the bottom side of the interposer 210, and thus the detailed description thereon is omitted for economy of explanation.

In some embodiments, the redistribution line (e.g., the redistribution pattern 224 and the redistribution via 226) may be disposed within the insulating layer 222. The redistribution line (e.g., the redistribution pattern 224 and the redistribution via 226) may include the redistribution pattern 224 and the redistribution via 226. The redistribution pattern 224 may extend longitudinally in the second direction D2 or the third direction D3. The redistribution via 226 may extend longitudinally in the first direction D1. The redistribution pattern 224 may be disposed within the same layer. Further, the redistribution pattern 224 may be disposed in layers spaced apart from each other in the first direction D1. Further, the redistribution via 226 may vertically connect the redistribution patterns 224, each of which is placed in a layer separated in the first direction D1. For example, the redistribution line (e.g., the redistribution pattern 224 and the redistribution via 226) may be a multi-layer structure in which at least one redistribution pattern 224 and at least one redistribution via 226 are alternately stacked (e.g., in the third direction D3). The redistribution pattern 224 and the redistribution via 226 may be surrounded by the insulating layer 222. In some embodiments, the insulating layer 222 may be a single layer as illustrated in FIG. 2. However, in some embodiments the insulating layer 222 may be composed of multiple layers and surround the redistribution line (e.g., the redistribution pattern 224 and the redistribution via 226).

In some embodiments, the redistribution line (e.g., the redistribution pattern 224 and the redistribution via 226) may include a conductive material. For example, in an embodiment the redistribution line (e.g., the redistribution pattern 224 and the redistribution via 226) may include at least one of copper (Cu), aluminum (Al), tin (Sn), indium (In), tungsten (W), lead (Pb), zinc (Zn), nickel (Ni), gold (Au), silver (Ag), antimony (Sb), bismuth (Bi), titanium (Ti) and combinations thereof. However, embodiments of the present disclosure are not necessarily limited thereto.

In some embodiments, a third connection pad 250 may be disposed on the front side of the redistribution layer 220. In an embodiment, the third connection pad 250 may include at least one of copper (Cu), aluminum (Al), tin (Sn), indium (In), lead (Pb), zinc (Zn), nickel (Ni), gold (Au), silver (Ag), antimony (Sb), bismuth (Bi) and combinations thereof. However, embodiments of the present disclosure are not necessarily limited thereto. The third connection pad 250 may be electrically connected to a redistribution line (e.g., the redistribution pattern 224 and the redistribution via 226). The third connection pad 250 may be exposed from the redistribution layer 220 through at least one opening formed in the redistribution passivation layer.

In some embodiments as shown in FIGS. 1-2, the semiconductor package 10 may include the first semiconductor chip 300 and the second semiconductor chip 400. However, embodiments of the present disclosure are not necessarily limited thereto and the semiconductor package 10 may include one semiconductor chip or three or more semiconductor chips in some embodiments. The first semiconductor chip 300 and the second semiconductor chip 400 may be arranged in the second direction D2. Further, the first semiconductor chip 300 and the second semiconductor chip 400 may be separated from each other. The first semiconductor chip 300 and the second semiconductor chip 400 may be disposed on the interposer structure 200 (e.g., disposed directly thereon in the first direction D1). For example, in an embodiment the first semiconductor chip 300 and the second semiconductor chip 400 may be disposed on the upper side of the interposer structure 200, and the bottom side of the first semiconductor chip 300 and the bottom side of the second semiconductor chip 400 may be arranged to face the front side of the interposer structure 200. For example, the front side of the first semiconductor chip 300 and the front side of the second semiconductor chip 400 may face the back side of the interposer structure 200. Accordingly, the first semiconductor chip 300 and the second semiconductor chip 400 may be mounted on the interposer structure 200. In some embodiments, flip-chip bonding may be provided with respect to the first semiconductor chip 300 and the second semiconductor chip 400. Further, the first semiconductor chip 300 and the second semiconductor chip 400 may be molded by a molding layer 500. For example, the molding layer 500 may surround each side of the first semiconductor chip 300 and the second semiconductor chip 400. Further, in an embodiment the molding layer 500 may surround a first connecting body 310 and a second connecting body 320 described later. In an embodiment, the molding layer 500 may be a resin including epoxy or polyimide. For example, the resin may include bisphenol-group epoxy resin, polycyclic aromatic epoxy resin, o-cresol novolac epoxy resin, biphenylgroup epoxy resin or naphthalene-group epoxy resin.

According to some embodiments, the first semiconductor chip 300 and the second semiconductor chip 400 may include logic chips and/or memory chips. For example, in an embodiment a logic chip may include a microprocessor, analog devices, or a digital signal processor. For example, the logic chip may be a microprocessor, such as a central processing unit (CPU), a graphic processing unit (GPU) and an application processor (AP), an analog device, or a digital signal processor. Further, the memory chip may include volatile memory chips such as dynamic random access memory (DRAM) or static random access memory (SRAM), and nonvolatile memory chips such as phase-change random access memory (PRAM), magnetoresistive random access memory (MRAM), ferroelectric random access memory (FeRAM), and resistive random access memory (RRAM). However, embodiments of the present disclosure are not necessarily limited thereto. In an embodiment, the first semiconductor chip 300 and the second semiconductor chip 400 may include a system on chip (SOC) that integrates all essential elements of the system, including the image chip including a CCD image sensor or a CMOS image sensor, microprocessor, memory, and input/output interface, into a single chip.

In some embodiments, the first semiconductor chip 300 and the second semiconductor chip 400 may be the same type of semiconductor chips as each other. However, embodiments of the present disclosure are not necessarily limited thereto. The first semiconductor chip 300 and the second semiconductor chip 400 may be different types of semiconductor chips. The first semiconductor chip 300 and the second semiconductor chip 400 have identical or similar structures, and thus hereinafter, for economy and ease of explanation, embodiments based on the first semiconductor chip 300 will be described.

In some embodiments, the first semiconductor chip 300 may include a substrate and a distribution structure. In an embodiment, the substrate of the first semiconductor chip 300 may include silicon (Si), for example, crystalline silicon, polycrystalline silicon, or amorphous silicon. Alternatively, the substrate of the first semiconductor chip 300 may include a semiconductor element such as germanium (Ge), or a compound semiconductor such as silicon carbide (SiC), gallium arsenide (GaAs), indium arsenide (InAs), and indium phosphide (InP). In some embodiments, the substrate of the first semiconductor chip 300 may have a SOI (silicon on insulator) structure. For example, the substrate of the first semiconductor chip 300 may include a buried oxide (BOX) layer. The substrate of the first semiconductor chip 300 may include a conductive area, for example, a doped well or a doped structure. Further, the substrate of the first semiconductor chip 300 may have various device isolation structures, such as a shallow trench isolation (STI) structure.

In some embodiments, the distribution structure of the first semiconductor chip 300 may be formed on the substrate of the first semiconductor chip 300. In an embodiment, the distribution structure of the first semiconductor chip 300 may include a multi-layered distribution pattern, a distribution via vertically connecting the distribution pattern of the multi-layer structure, and an insulating layer for insulating the distribution pattern and distribution via of the multi-layer structure. The insulating layer may have a single-layer or multi-layer structure. The distribution pattern and the distribution via may include a conductive material.

In some embodiments, the first semiconductor chip 300 may include at least one circuit device. The circuit device of the first semiconductor chip 300 may be electrically connected to the interposer structure 200 and the package substrate 100. In an embodiment, the circuit device of the first semiconductor chip 300 may be electrically connected to the redistribution line (e.g., the redistribution pattern 224 and the redistribution via 226) of the redistribution layer 220 through the first connecting body 310 and the second connecting body 320 described later. Through this, the circuit device may exchange electrical signals with the through via 215 of the interposer 210 and the distribution circuit formed within the package substrate 100, respectively.

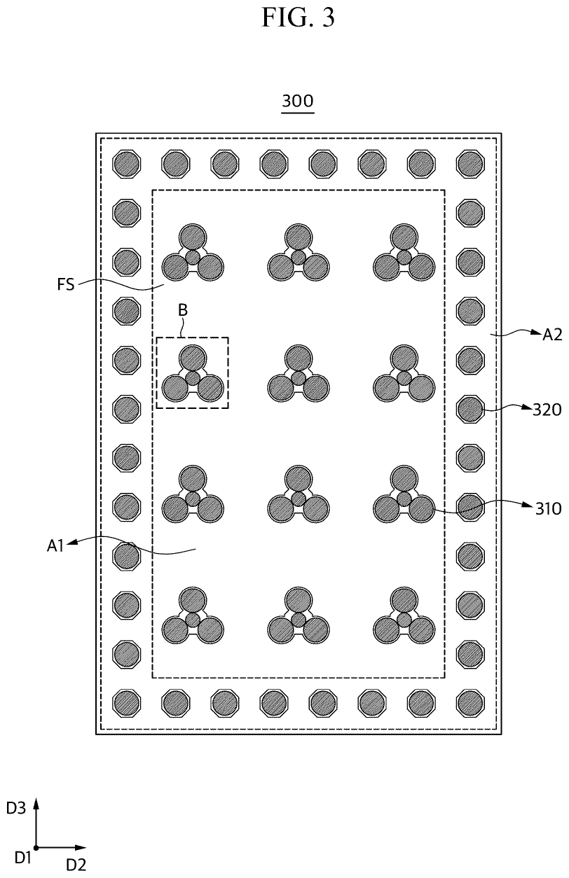

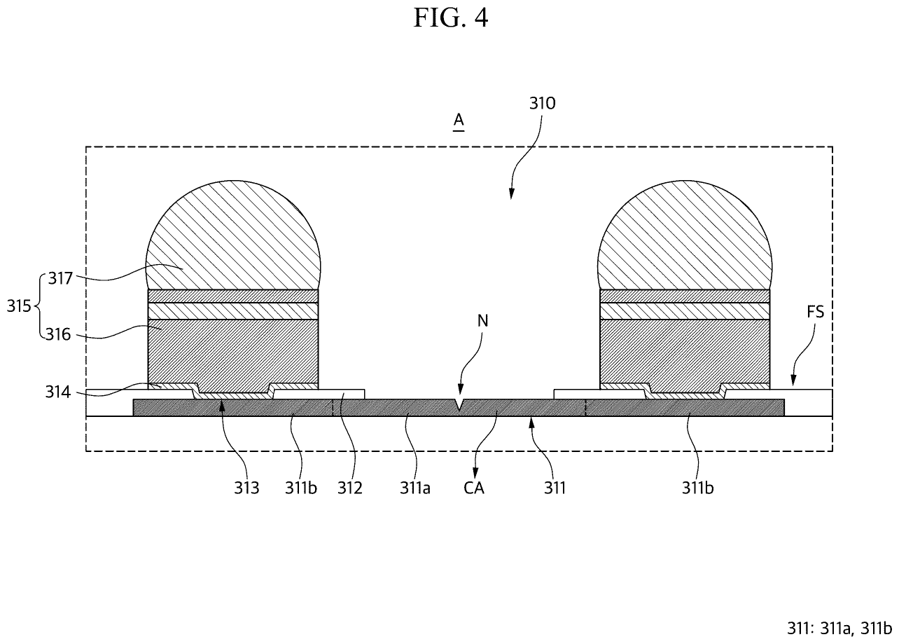

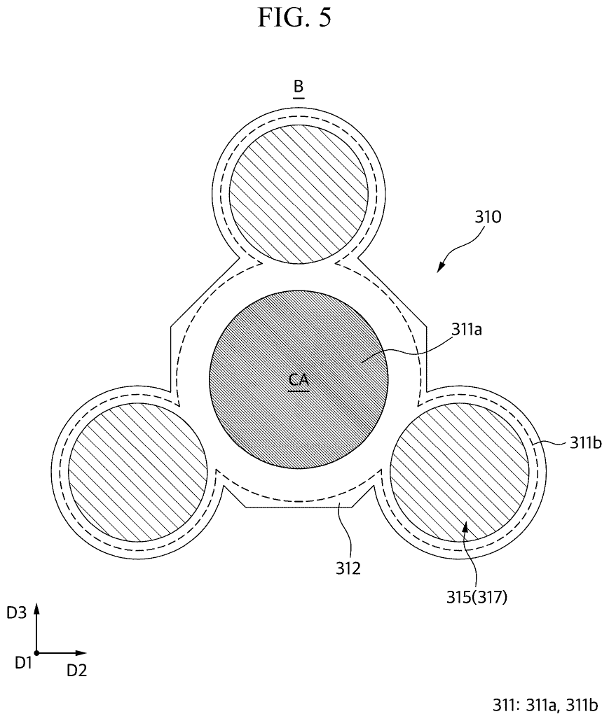

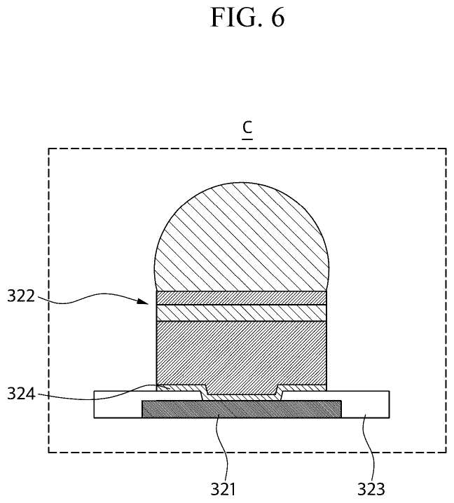

FIG. 3 is a drawing schematically illustrating a first semiconductor chip of FIG. 2 as viewed from a front side. FIG. 4 is a drawing schematically illustrating an enlarged view of a part A of FIG. 2. FIG. 5 is a drawing schematically illustrating an enlarged view of a part B of FIG. 3. FIG. 6 is a drawing schematically illustrating an enlarged view of the part C of FIG. 2. The dotted lines illustrated in FIG. 5 schematically represent the first pad covered by the passivation layer. FIGS. 4 and 6 may be shown in an inverted orientation as compared with FIG. 2.

Hereinafter, detailed described with reference to FIGS. 1 to 6 are embodiments in which the first semiconductor chip 300 is electrically connected to the interposer structure 200 through the first connecting body 310 and the second connecting body 320.

In some embodiments, the first connecting body 310 and the second connecting body 320 may be formed on (e.g., disposed directly thereon) the first semiconductor chip 300. For example, in an embodiment the first connecting body 310 and the second connecting body 320 may be formed on (e.g., disposed directly thereon) the bottom side of the first semiconductor chip 300, such as on the front side of the first semiconductor chip 300. The first connecting body 310 and the second connecting body 320 may be spaced apart from each other (e.g., in the second direction D2). In an embodiment, a plurality of first connecting bodies 310 and a plurality of second connecting bodies 320 may be formed on (e.g., disposed directly thereon) the front side of the first semiconductor chip 300.

In some embodiments, the plurality of first connecting bodies 310 may be formed in (e.g., disposed solely therein) a first area A1 of the first semiconductor chip 300. Further, in an embodiment the plurality of second connecting bodies 320 may be formed in (e.g., disposed solely therein) a second area A2 of the first semiconductor chip 300. Here, the first area A1 may refer to a core area of the first semiconductor chip 300 when the first semiconductor chip 300 is seen from the front side (e.g., when viewed in a plan view). The second area A2 may refer to a sub-area surrounding the core area of the first semiconductor chip 300 when the first semiconductor chip 300 is seen from the front side (e.g., when viewed in a plan view). For example, the second area A2 may be a sub-area that comprises a remaining area of the front side of the first semiconductor chip 300 that does not include the first area A1 (e.g., the core area). As illustrated in FIG. 3, the core area may be a generally rectangular area. However, the shape of the core area is not necessarily limited thereto, and the shape of the core area may vary, such as depending on design conditions. The distribution type (e.g., layout) of the first connecting body 310 formed in the first area A1 and the distribution type (e.g., layout) of the second connecting body 320 formed in the second area A2 illustrated in FIG. 3 are mere embodiments, and the layout may vary, such as depending on design conditions.

In some embodiments, the first connecting body 310 may include a first pad 311 and a first bump 315. The first pad 311 may be disposed on the front side of the first semiconductor chip 300. In some embodiments, the first pad 311 may be disposed inside the first semiconductor chip 300. The first pad 311 may be electrically connected to the distribution structure of the first semiconductor chip 300 described above and/or the circuit device of the first semiconductor chip 300.

In some embodiments, the first pad 311 may contain a conductive material. For example, in an embodiment the first pad 311 may include at least one of copper (Cu), aluminum (Al), tin (Sn), indium (In), tungsten (W), lead (Pb), zinc (Zn), nickel (Ni), gold (Au), silver (Ag), antimony (Sb), bismuth (Bi), titanium (Ti), and combinations thereof. However, embodiments of the present disclosure are not necessarily limited thereto.

In some embodiments, the first pad 311 may include a central area CA. The central area CA may be an area that includes the center of the first pad 311 when the first pad 311 is seen from the front side (e.g., when viewed in a plan view). The first pad 311 may include a center pad 311a and an edge pad 311b. The center pad 311a may be disposed on the central area CA of the first pad 311. The edge pad 311b may be disposed outside of the center pad 311a (e.g., in a plan view). In an embodiment, the center pad 311a and the edge pad 311b may be formed integrally with each other. Alternatively, the front side and the bottom side of each of the center pad 311a and the edge pad 311b may be positioned on a same plane. In an embodiment, the center pad 311a and the edge pad 311b may be generally circular in shape (e.g., in a plan view). However, embodiments of the present disclosure are not necessarily limited thereto and the shapes of the center pad 311a and the edge pad 311b may vary. Further, in some embodiments, the diameter of the center pad 311a may be approximately 66 μm, and the diameter of the edge pad 311b may be approximately 30 μm.

In some embodiments, a plurality of edge pads 311b may be disposed on the outside of the center pad 311a to surround the center pad 311a (e.g., in a plan view). For example, in an embodiment, based on the center pad 311a disposed on the central area CA of the first pad 311, three edge pads 311b may be disposed on the edges of the center pad 311a. For example, the edge pads 311b may be positioned along the perimeter of the center pad 311a. In an embodiment, the three edge pads 311b may be spaced equally apart from each other (e.g., in a plan view). For example, the three edge pads 311b may be spaced 120 degrees apart from the center on the front side of the center pad 311a. Accordingly, the arrangement of the three edge pads 311b may form a roughly triangular shape.

In some embodiments, a passivation layer 312 may be disposed on the first pad 311 (e.g., disposed directly thereon). In an embodiment, the passivation layer 312 may be formed by applying a material including a solder resist manufactured from an organic material such as epoxy, acrylic and polyimide. However, the passivation layer 312 is not necessarily limited thereto.

In some embodiments, the passivation layer 312 may be disposed on the front side of the first semiconductor chip 300. The passivation layer 312 may be positioned to expose the central area CA of the first pad 311. For example, the passivation layer 312 may expose the center pad 311a on the front side of the first semiconductor chip 300. Further, the passivation layer 312 may be arranged to cover the front side of the edge pad 311b. Here, the passivation layer 312 may form an opening part 313 to expose a specific area of the edge pad 311b. In an embodiment, the specific area that is exposed may be an area that includes the center of the edge pad 311b when the edge pad 311b is seen from the front side (e.g., when viewed in a plan view). The center pad 311a may include one side that is exposed to an outside of the first semiconductor chip 300.

In some embodiments, an under bump metallization (UBM) layer 314 may be disposed on the edge pad 311b (e.g., disposed directly thereon in the first direction D1). The UBM layer 314 may be arranged between the first bump 315 and the edge pad 311b (e.g., in the first direction D1), which will be described later. For example, in an embodiment the UBM layer 314 may be manufactured from materials including chromium (Cr) and titanium (Ti) for joint reliability, Nickel (Ni) for diffusion prevention, a material containing tungsten (W) and/or copper (Cu) for electrical connections and wettability and gold (Au).

In some embodiments, the UBM layer 314 may be arranged to fill the opening part 313 formed by the passivation layer 312. For example, as illustrated in FIG. 4, a portion of the bottom side that is filled in the opening part 313 of the bottom side of the UBM layer 314 may come into direct contact with the edge pad 311b. Accordingly, the UBM layer 314 and the edge pad 311b may be electrically connected to each other. Further, the portion of the bottom side of the UBM layer 314 may be in direct contact with the front side of the passivation layer 312. Further, the front side of the UBM layer 314 may directly contact the bottom side of a pillar 316 described later. A side of the UBM layer 314 may be exposed, such as lateral edges of the UBM layer 314.

In some embodiments, the first bump 315 may transmit signals between the first semiconductor chip 300 and the interposer structure 200. For example, in an embodiment the first bump 315 may be a power bump that transmits a power signal. The first bump 315 may transmit and receive power signals between the first semiconductor chip 300 and the interposer structure 200. The first bump 315 may be disposed on the edge pad 311b (e.g., in the first direction D1). The first bump 315 may be disposed between the third connection pad 250 and the edge pad 311b (e.g., in the first direction D1). Alternatively, the first bump 315 may directly contact the UBM layer 314. For example, as illustrated in FIG. 4, the bottom side of the first bump 315 may make direct contact with the front side of the UBM layer 314.

In some embodiments, a plurality of first bumps 315 may be disposed on the edge pad 311b. In an embodiment the number of first bumps 315 may be provided equal to the number of edge pads 311b. For example, in an embodiment in which three edge pads 311b are disposed, three first bumps 315 may also be disposed on the edge pads 311b. For example, the first bumps 315 and the edge pads 311b may be arranged to correspond to each other in a one-to-one arrangement. In this embodiment, based on one center pad 311a, three edge pads 311b and three first bumps 315 may be formed. Accordingly, the three first bumps 315 may be equally spaced radially around the central area CA of the first pad 311. Further, the diameter of the multiple first bumps 315 may all be the same as each other. For example, in an embodiment the diameter of multiple first bumps 315 may be approximately 25 μm. Further, tips of multiple first bumps 315 may lie on the same virtual plane as each other. For example, the tips of the multiple first bumps 315 may have the same vertical level (e.g., in the first direction D1) with respect to the front side of the first semiconductor chip 300.

In some embodiments, the first bump 315 may include the pillar 316 and a micro bump 317. The pillar 316 may generally have a pillar shape. The pillar 316 may be disposed on (e.g., disposed directly thereon) the UBM layer 314. As illustrated in FIG. 4, the pillar 316 may be positioned so that a bottom side of the pillar 316 directly contacts the front side of the UBM layer 314. Further, the pillar 316 may have a multi-layer structure. For example, in an embodiment the pillar 316 have a structure in which copper (Cu) and nickel (Ni) are alternately laminated (e.g., in the first direction D1). However, embodiment of the present disclosure are not necessarily limited thereto and the structure of the pillar 316 may vary. The pillar 316 may have a structure in which various conductive materials are laminated. The micro bump 317 may generally have a cap shape. The micro bump 317 may be disposed on the pillar 316. For example, in an embodiment the micro bump 317 may be formed on (e.g., disposed directly thereon) the upper side of the pillar 316 through the reflow process. The micro bump 317 may include a conductive material. The tip of the micro bump 317 may make direct contact with the third connection pad 250. Accordingly, the first bump 315 and the third connection pad 250 may be electrically connected to each other. Further, the plurality of first bumps 315 formed on each of the edge pads 311b may also be electrically connected to the center pad 311a which is formed integrally with the edge pads 311b.

In some embodiments, a notch N may be formed in the exposed area of the first pad 311 which is exposed to an outside of the semiconductor device, such as the first semiconductor chip 300. For example, the notch N may be formed in (e.g., positioned at) the central area CA of the first pad 311. Further, the notch N may be formed on the front side of the first pad 311, and the notch N may be recessed towards the back side of the first pad 311 (e.g., recessed towards the upper part structure S2). In an embodiment, the notch N may be formed by a probe pin directly contacting the front side of the first pad 311 to determine whether the first pad 311 is defective. For example, the notch N may be formed during the process of determining whether the center pad 311a and the edge pads 311b are defective. Further, the notch N may also be formed during the process of determining whether the first bumps 315 disposed on the edge pads 311b are defective. For example, in an embodiment the notch N may be a measurement point of an Energy Dispersive X-ray Spectroscopy (EDS) of the first pad 311 and the first bump 315.

In the existing technology, an EDS test is performed by directly contacting the probe pin to the top of the bump to identify defects in pads or bumps. However, in this comparative embodiment, damage to the top of the bump causes poor contact of the bump, such as non-wet phenomenon, and in some severe cases, there is a risk that the bump structure itself collapses. For example, in the case of micro bumps, there is a problem that direct defect inspection is difficult because the size of the upper part is very small.

According to some embodiments described above, a probe pin may be directly contacted to the exposed central area CA of the first pad 311. For example, by directly contacting the probe pin on the exposed area of the first pad 311 (e.g., the exposed area of the center pad 311a), each of the center pads 311a, the edge pads 311b and the first bumps 315 electrically connected to the edge pads 311b may be inspected for defects. Accordingly, since direct contact with the bumps may also be avoided when inspecting the bumps for defects, the possibility of causing damage in the form of bumps may be prevented. As a result, the contact reliability of the bump may be reconsidered, and thus the reliability of the semiconductor package may be increased.

In some embodiments, the second connecting body 320 may include a second pad 321 and a second bump 322. The second pad 321 is disposed on (e.g., disposed directly thereon) the front side of the first semiconductor chip 300 and may be electrically connected to a distribution structure of the first semiconductor chip 300 and/or a circuit device of the first semiconductor chip 300. In some embodiments, the second pad 321 may be disposed inside the first semiconductor chip 300. Further, a portion of the front side and sides of the second pad 321 may be surrounded by a passivation layer 323. In an embodiment, the front side of the second pad 321, which is exposed and not surrounded by the passivation layer 323, may be covered by a UBM layer 324. Additionally, a front side of the UBM layer 324 may directly contact the back side of the second bump 322. In an embodiment, the passivation layer 323 may include a solder resist, and the UBM layer 324 may include a conductive material.

In some embodiments, the second pad 321 may include a conductive material. The second pad 321 contains the same or similar material as the first pad 311 described above, and thus the description thereon is omitted for economy of explanation. In an embodiment, the second pad 321 may be roughly circular in shape, and may be transformed into various forms. The diameter of the second pad 321 may correspond to the diameter of the edge pad 311b. For example, in an embodiment the diameter of the second pad 321 may be approximately 30 μm.

In some embodiments, the second bump 322 may include pillars and micro bumps, similar to the first bump 315 described above. The pillars and the micro bumps of the second bump 322 are mostly identical to or similar to those of the first bump 315, and thus description on the pillar and the micro bump of the second bump 322 in detail is omitted for economy of explanation.

In some embodiments, the second bump 322 may be disposed on the second pad 321. For example, the back side of the second bump 322 and the front side of the UBM layer 324 are disposed to be in direct contact, and a portion of a back side of the UBM layer 324 and the second pad 321 are disposed in direct contact, and thus the second bump 322 may be electrically connected to the second pad 321. The second bump 322 may transmit signals between the first semiconductor chip 300 and the interposer structure 200. For example, the tip of the micro bump 317 of the second bump 322 may make direct contact with the third connection pad 250 for electrical connection between the first semiconductor chip 300 and the interposer structure 200. In an embodiment the second bump 322 may be a signal bump that transmits a data signal (for example, an input/output signal). Accordingly, the first semiconductor chip 300 and the interposer structure 200 may exchange data signals through the second bump 322. Further, in some embodiments the second bump 322 may be electrically connected to the second pad 321 via a layer containing a conductive material separately from the aforementioned UBM layer 324.

In some embodiments, the second bump 322 may be matched one-to-one with the second pad 321. For example, the second bump 322 and the second pad 321 may be arranged to correspond to each other in a one-to-one arrangement. For example, the number of second pads 321 and the number of the second bumps 322 may be arranged in a one-to-one ratio. For example, any one second pad 321 may have any one second bump 322 disposed on it. The second bump 322 may contain a conductive material. In some embodiments, the cross-sectional area of the second bump 322 may be the same as (e.g., identical to) the cross-sectional area of the first bump 315. For example, the diameter of the second bump 322 may be the same as the diameter of the first bump 315. In an embodiment, the diameter of the second bump 322 may be approximately 25 μm. For example, the diameter of the second bump 322 may be the same as the diameter of the first bump 315. Further, the tip of the second bump 322 may be on the same virtual plane as the tip of the first bump 315. For example, the tip of the second bump 322 may have the same vertical level (e.g., in the first direction D1) as the tip of the first bump 315 with respect to the front side of the first semiconductor chip 300. For example, the vertical levels of the tips of the pillars 316 of the first bumps 315 and the tips of the pillars of the second bumps 322 may be the same as each other (e.g., identical to each other).

In some embodiments, the cross-sectional areas of the first bump 315 and the second bump 322 may be the same as each other, and the vertical levels of the tip of the first bump 315 and the tip of the second bump 322 may be the same as each other. Thus, in an embodiment, when the first bump 315 and the second bump 322 are formed on the first semiconductor chip 300, the first bump 315 and the second bump 322 may be formed simultaneously. Accordingly, simplification of the semiconductor package manufacturing process may be achieved. Further, since the tip of the first bump 315 and the tip of the second bump 322 lie on the same virtual plane, the contact reliability with the lower part structure, such as the interposer structure 200, may be increased, and the flatness of the entire structure is increased. Therefore, the warpage or mechanical stress susceptibility of the structure may be minimized.

In addition, for a power bump that transmits a power signal, the capacitance per unit area must be relatively higher than that of a signal bump that transmits a data signal. For example, the larger the diameter of the power bump, the greater the capacitance per unit area, which is advantageous in terms of signal transmission. According to some embodiments described above, a plurality of first connecting bodies 310 may be disposed on the first area A1 of the first semiconductor chip 300, and a plurality of second connecting bodies 320 may also be disposed on the second area A2 of the first semiconductor chip 300. In an embodiment, each first connecting body 310 is grouped with the plurality of first bumps 315. However, since each second connecting body 320 is composed of one second bump 322, the capacitance per unit area of one connecting body is greater for the first connecting body 310 than for the second connecting body 320. Accordingly, it is possible to have a distribution type (e.g., layout) that satisfies both the power bump requirement and the signal bump requirement. Further, the pad area located in the core area of the first semiconductor chip 300 (e.g., the first area A1) may increase, thereby reducing the current density, and thus electromigration (EM) characteristics may be enhanced. In addition, the multiple first bumps 315 are disposed on each first connecting body 310 to satisfy high capacitance per unit area while occupying a relatively small space, and thus the degree of freedom of distribution type (e.g., layout) may increase depending on design requirements.

In embodiments described above, it is described that the first bump 315 is the power bump, and the second bump 322 is the signal bump. However, embodiments of the present disclosure are not necessarily limited thereto. For example, in an embodiment the first bump 315 may be a bump that transmits signals that require relatively high capacitance per unit area, and the second bump 322 may be a bump that transmits signals that require relatively low capacitance per unit area. Further, the edge pad 311b and the first bump 315 may be spaced apart from each other at different intervals.

Further, in embodiments described above, it is described that the first bump 315 and the second bump 322 contain pillars and micro bumps. However, embodiments of the present disclosure are not necessarily limited thereto. For example, in an embodiment the first bump 315 and the second bump 322 may be solder balls. In this embodiment, the first bump 315 and the second bump 322 may be electrically connected to the first pad 311 and the second pad 321 through a layer containing a conductive material.

Hereinafter, the first connecting body 310 according to some embodiments will be described. Hereinafter, except for the arrangement of the edge pad 311b and the first bump 315 described below, the first connecting body 310 has a structure and function that are mostly identical or similar to the semiconductor package described with reference to FIGS. 1 to 6. Therefore, repetitive descriptions of similar or identical elements may be omitted for economy of explanation.

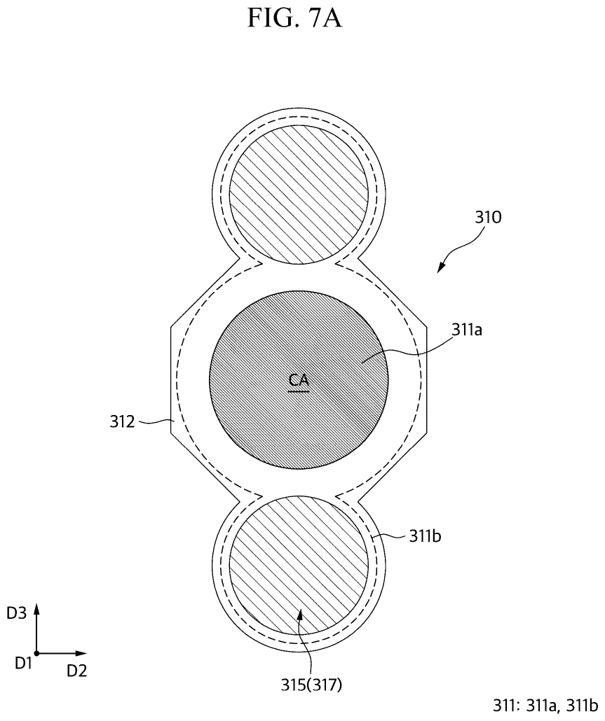

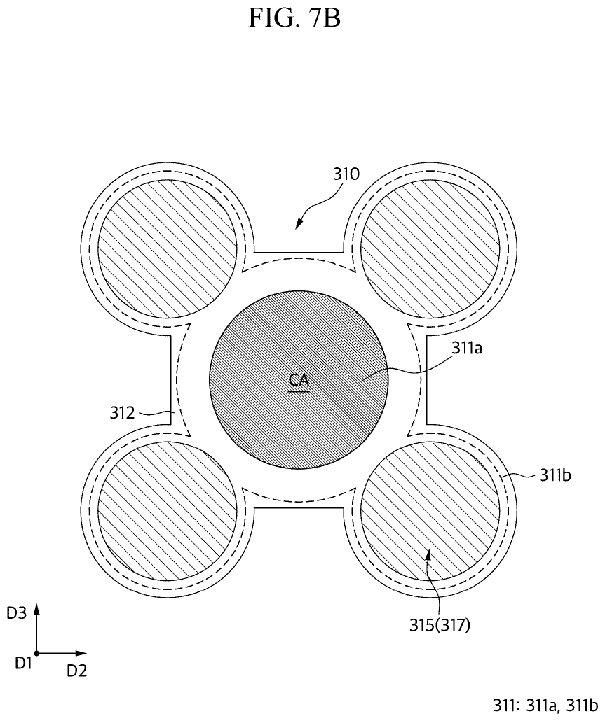

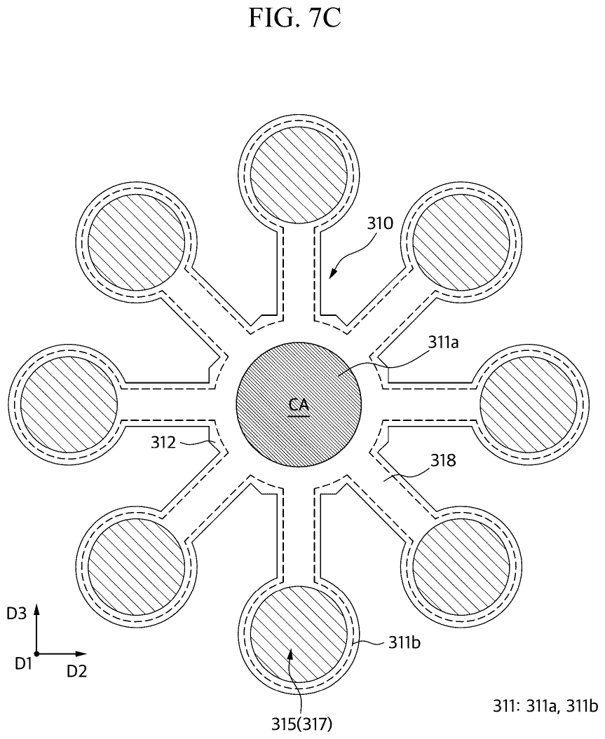

Referring to FIG. 7A, two edge pads 311b may be disposed at the edges of the center pad 311a. Further, the first bumps 315 may be disposed on the edge pads 311b. For example, there may be two first bumps 315. The plurality of first bumps 315 may be disposed at equal intervals based on the center of the center pad 311a. For example, one first bump 315 and the other first bump 315 may be disposed to face each other (e.g., in the third direction D3) with the center pad 311a interposed therebetween when viewed from the front side of the first pad 311 (e.g., when viewed in a plan view).

Referring to FIG. 7B, in an embodiment four first bumps 315 may be disposed on the edge of the center pad 311a. The plurality of first bumps 315 may be spaced apart with respect to the center of the center pad 311a, and the angle between the imaginary lines connecting the centers of the adjacent first bumps 315 and the center pad 311a may be about 90 degrees. For example, the plurality of first bumps 315 may have a generally square shape when the first pad 311 is viewed from the front side (e.g., when viewed in a plan view).

Referring to FIG. 7C, the first connecting body 310 may further include a connection pad 318. For example, the connection pad 318 may be connected to (e.g., directly connected thereto) the edge of the center pad 311a. Further, the connection pad 318 may be connected to (e.g., directly connected thereto) each of the plurality of edge pads 311b. In an embodiment, the center pad 311a, the edge pad 311b and the connection pad 318 may be formed integrally with each other, and may be electrically connected to each other. For example, the edge pad 311b and the first bumps 315 disposed on the edge pads 311b may be electrically connected to the center pad 311a via the connection pad 318. The passivation layer 312 may be disposed on the connection pad 318, and the passivation layer 312 may cover one side of the connection pad 318. In an embodiment as shown in FIG. 7C, eight first bump 315 may be disposed on the edge pads 311b. However, embodiments of the present disclosure are not necessarily limited thereto. For example, in an embodiment, N number of the edge pads 311b and N number of the first bump 315 may be provided in which N is a natural number greater than or equal to 5, and each edge pad 311b may be formed integrally with and electrically connected to the center pad 311a.

In embodiments described above, the edge pad 311b and the first bump 315 may be spaced apart from each other at different intervals.

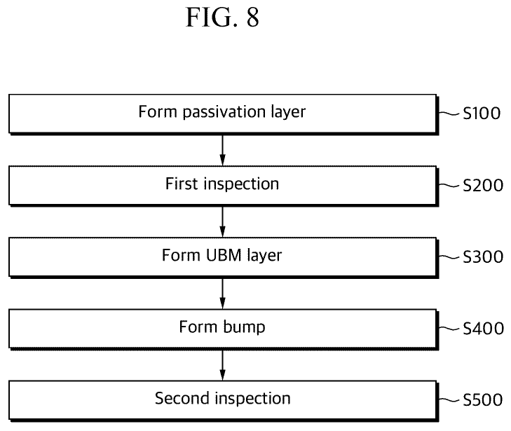

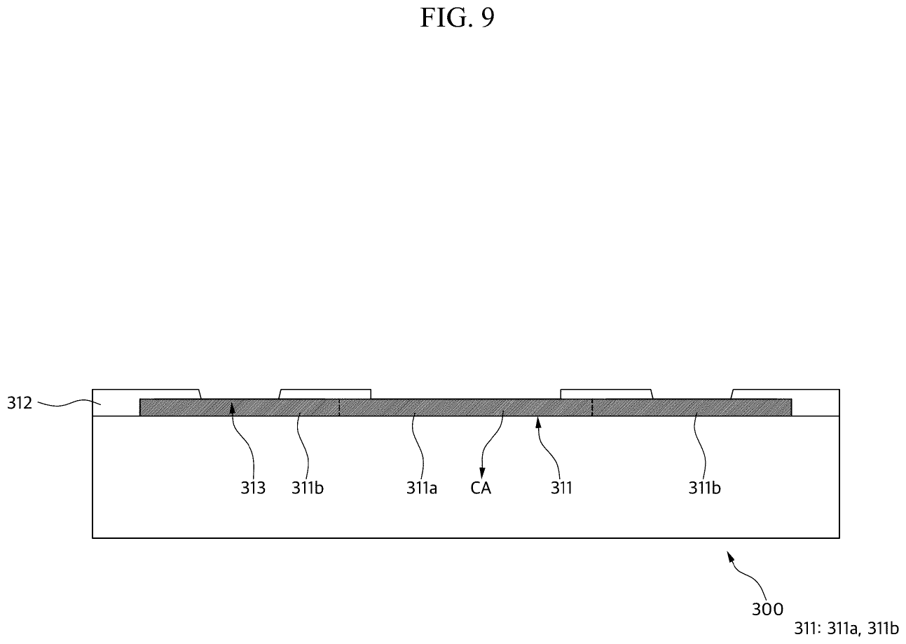

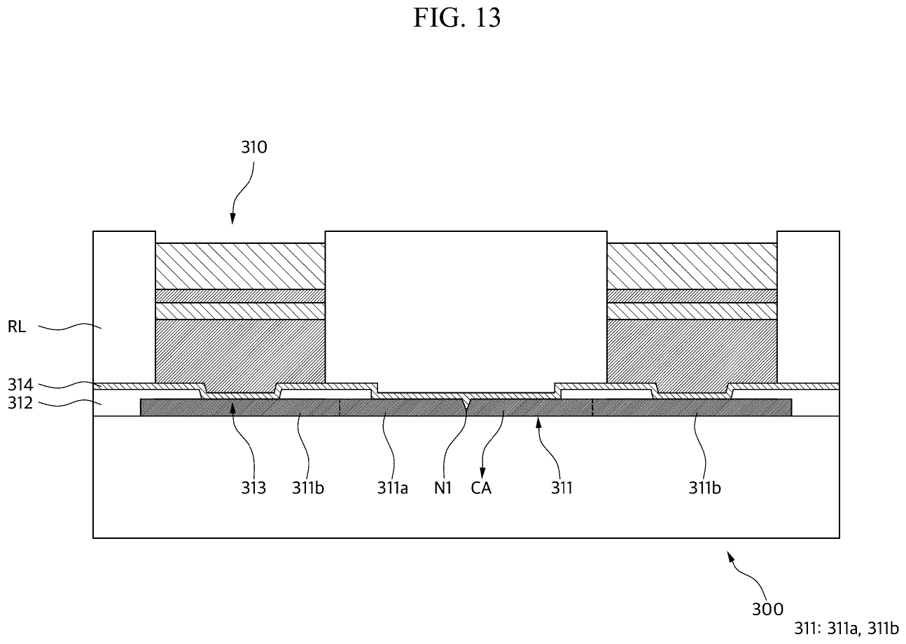

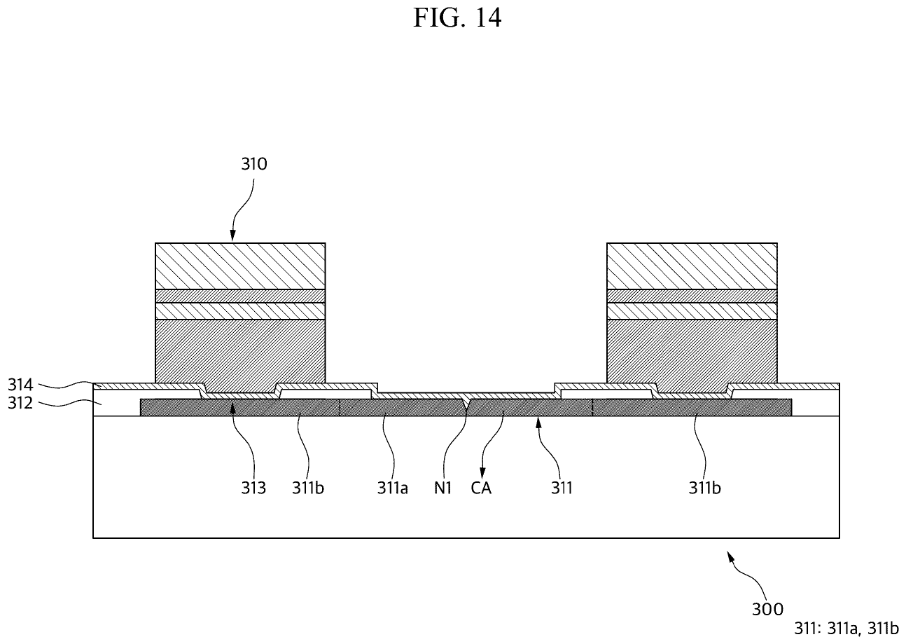

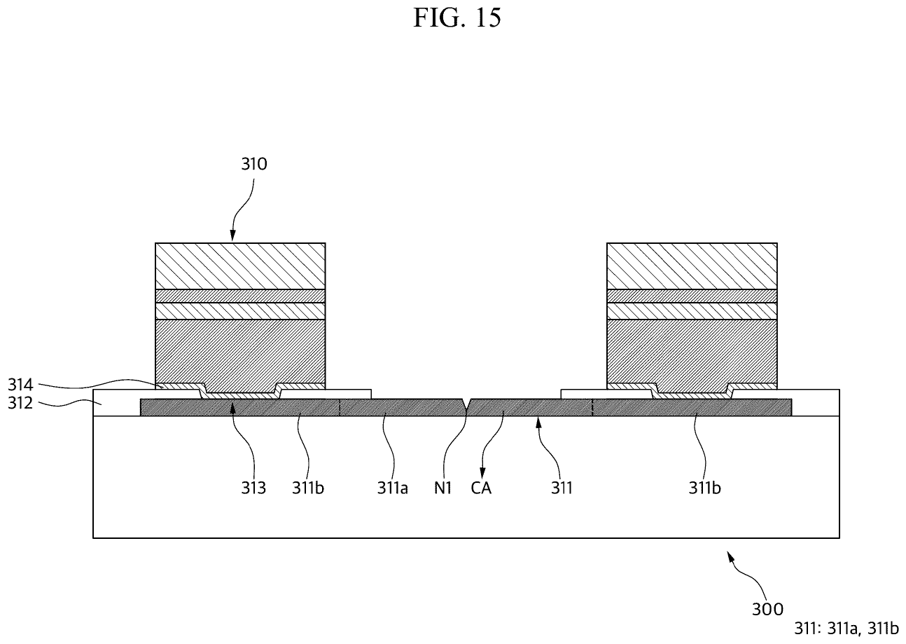

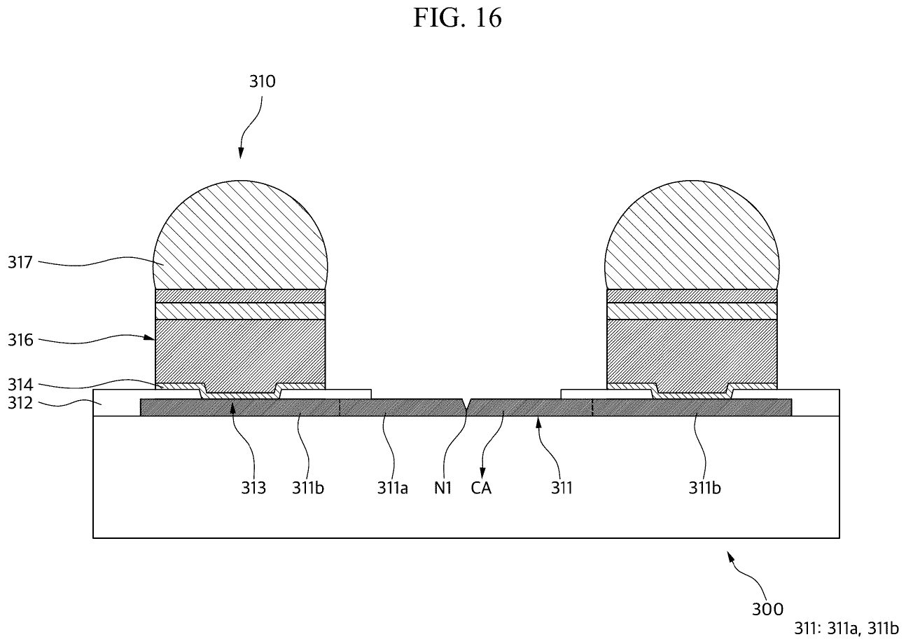

FIG. 8 is a flowchart illustrating a method for manufacturing a semiconductor package according to an embodiment. FIGS. 9 to 17 are cross-sectional views of intermediate operations for explaining a method for manufacturing a semiconductor package according to an embodiment.

Referring to FIG. 8, a method of manufacturing a semiconductor package may sequentially include forming a passivation layer in operation S100, performing a first inspection in operation S200, forming an UBM layer in operation S300, forming a bump in operation S400 and performing a second inspection in operation S500. In an embodiment, the forming of a passivation layer in operation S100, the performing of the first inspection in operation S200, the forming of an UBM layer in operation S300, the forming of a bump in operation S400 and the performing of the second inspection in operation S500 may be performed sequentially.

Referring to FIG. 9, before forming the passivation layer in operation S100, the first semiconductor chip 300 including a substrate, a distribution structure and the first pad 311 may be provided. At a previous stage, when the first pad 311 is placed on the front side of the first semiconductor chip 300, the center pad 311a and the edge pad 311b may be formed integrally with each other. The passivation layer 312 is formed on the first semiconductor chip 300 in operation S100 where the passivation layer is formed. For example, the passivation layer 312 may be formed after the first pad 311 is formed.

In an embodiment, in operation S100 where the passivation layer is formed, a material including solder resist may be applied to (e.g., disposed on) the entire front side of the first pad 311 to form the passivation layer 312. Afterwards, a portion of the passivation layer 312 may be removed to expose the first pad 311 on the lower side of the passivation layer 312 on the first semiconductor chip 300. For example, in an embodiment a cavity may be formed in the passivation layer 312 through exposure and development processes. In an embodiment, the cavity may be formed on the central area CA of the first pad 311, such as on the center pad 311a. Further, the cavity may be formed on edge pad 311b. As described above, the cavity formed on the edge pad 311b may be the opening part 313 in which the edge pad 311b is exposed and filled with a UBM layer.

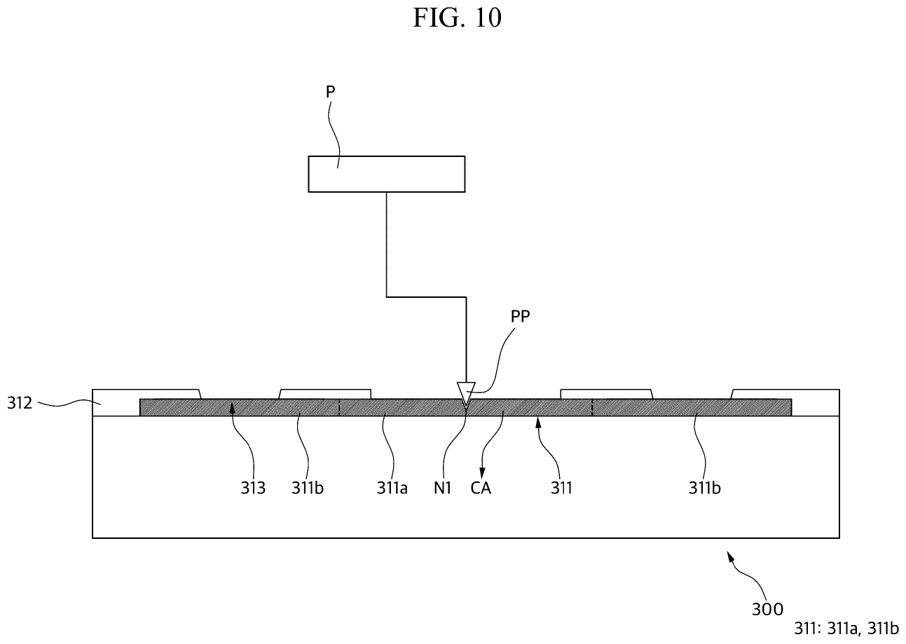

Referring to FIG. 10, in the performance of the first inspection of operation S200, the first semiconductor chip 300 is inspected for defects using a probe card P. The probe card P contains a probe pin PP. In an embodiment, in the first specification of operation S200, the probe pin PP may be brought into direct contact with the central area CA of the first pad 311 exposed by the cavity, such as the center pad 311a. As described above, the center pad 311a may be electrically connected to a distribution structure of the first semiconductor chip 300 and/or a circuit device of the first semiconductor chip 300, and may also be electrically connected to the edge pads 311b. Accordingly, by directly contacting the probe pin PP to the center pad 311a, the electrical short and leakage current may be measured to inspect for defects in the center pad 311a and the edge pads 311b, and the electrical connections between the circuit devices and distribution structures inside the first semiconductor chip 300 may also be inspected for defects. In the process of bringing the probe pin PP into direct contact with the center pad 311a, a notch N1 may be formed on the front side of the center pad 311a. As described above, since no structures such as bumps are stacked on the center pad 311a, the structural stability of the first semiconductor chip 300 is not deteriorated by the notch N1.

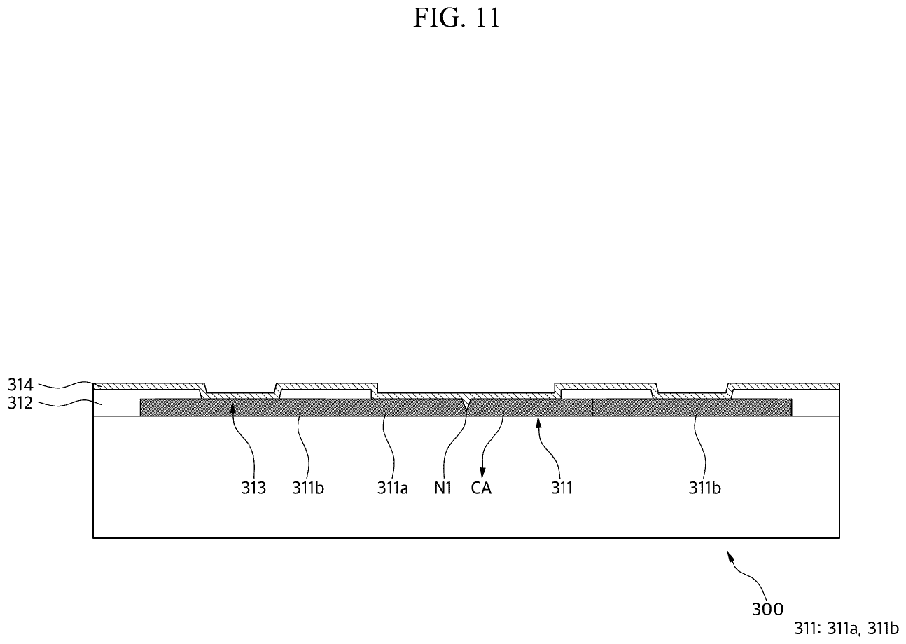

Referring to FIG. 11, the operation S300 where the UBM layer is formed may be performed after both the forming of the passivation layer in operation S100 and the first inspection in operation S200 are completed, and after performing a cleaning process on the first semiconductor chip 300. In an embodiment, the cleaning process may include dry cleaning using a cleaning plasma generated by exciting a cleaning gas. However, embodiments of the present disclosure are not necessarily limited thereto, and the chemical cleaning process may be further included. In the operation S300 where the UBM layer is formed, the UBM layer 314 is formed on the front side FS of the first semiconductor chip 300. Specifically, the UBM layer 314 may be laminated on (e.g., directly thereon) the first pad 311 and on the passivation layer 312. For example, in an embodiment the UBM layer 314 may be thinly deposited on the first pad 311 and the passivation layer 312 using a sputtering process (Seed Sputtering). However, embodiments of the present disclosure are not necessarily limited thereto.

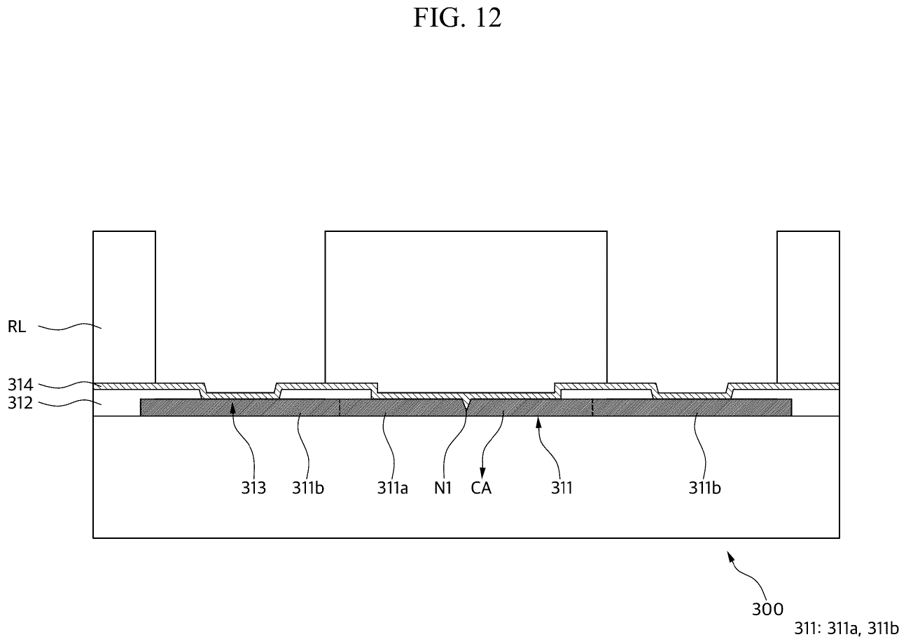

Referring to FIGS. 12 to 16, in operation S400 where the bump is formed, the first bump 315 may be formed on the first pad 311. For example, in operation S400 where the bump is formed, the center pad 311a may be exposed and the first bump 315 may be formed on the edge pad 311b. In an embodiment, in operation S400 where the bump is formed, a resist layer coating, electroplating, resist layer removal, and reflow processes may be performed sequentially.

For example, in an embodiment a resist layer RL may be coated on the UBM layer 314. In some embodiments, the resist layer RL may include photoresist. In an embodiment, the resist layer RL may be coated on the entire area of one side of the UBM layer 314, and the resist layer RL in the area corresponding to the edge pad 311b may be removed through the exposure process and the development process. After the resist layer RL is removed, a layer of conductive material may be formed on the edge pad 311b through an electroplating process. For example, in an embodiment, in the electroplating process, a copper (Cu) layer, a nickel (Ni) layer, a copper (Cu) layer, and a solder layer may be sequentially laminated on the edge pad 311b. However, embodiments of the present disclosure are not necessarily limited thereto, and layers containing various conductive materials may be laminated. After a layer containing the conductive material is formed in the area where the resist layer RL is removed, all of the remaining resist layer RL is removed. For example, in an embodiment the removal of the remaining resist layer RL may be accomplished through a strip process. In an embodiment, after the resist layer RL is completely removed, the unnecessary UBM layer 314 is etched on the first semiconductor chip 300. For example, the remaining UBM layer 314, except for the UBM layer 314 formed in the area corresponding to the edge pad 311b, may be etched. For example, in an embodiment the UBM layer 314 may be removed using a chemical etchant, or may be removed using the gas of excited reaction. Once the exposed UBM layer 314 is removed, a solder layer may be formed into a cap shape through a reflow process. For example, in an embodiment the solder layer may be melted by heating the solder layer in an oven, and the molten solder layer may be formed into a cap shape by surface tension. The copper (Cu) layer, the nickel (Ni) layer, and the copper (Cu) layer formed in the process are referred to as the pillar 316, and the solder layer may be referred to as the micro bump 317.

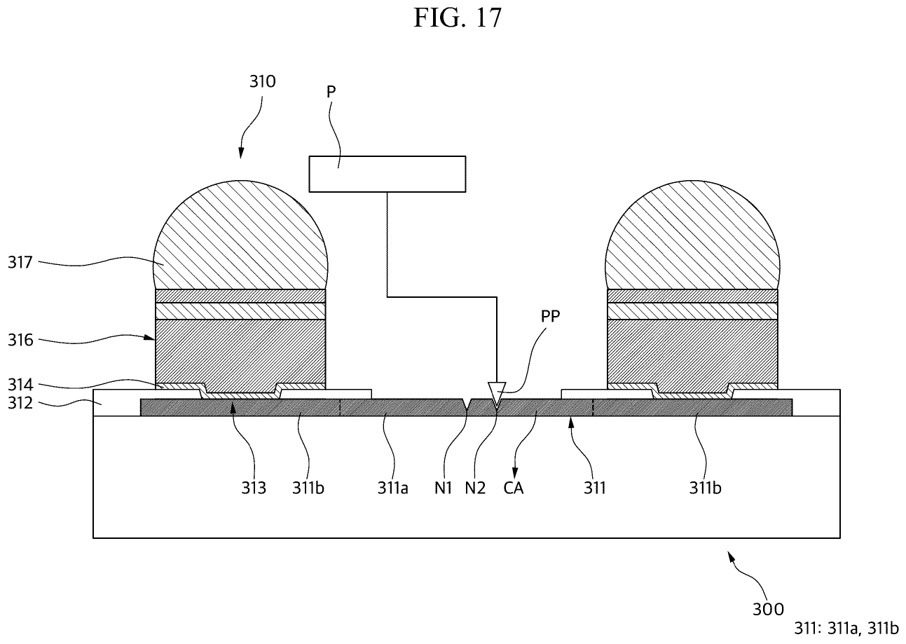

Referring to FIG. 17, in the second inspection in operation S400, the probe pin PP of the probe card P may be brought into direct contact with the central area CA of the exposed the first pad 311, such as the center pad 311a. As described above, the first bump 315 may be electrically connected to the center pad 311a via the edge pads 311b. Accordingly, the probe pin PP is brought into direct contact with the center pad 311a to measure data such as short circuit and current, and the first bumps 315 formed afterwards are inspected collectively for defects. In an embodiment, a notch N2 may also be formed on the center pad 311a in the second inspection of operation S400. In an embodiment, the notch N2 may be formed in a different location from the notch N1 formed in the first inspection of operation S200 for increased structural stability. For example, a position where the probe pin PP is brought into direct contact with the center pad 311a in the first inspection of operation S200 may be different from a position where the probe pin PP is brought into direct contact with the center pad 311a in the second inspection of operation S400. Accordingly, the notch N (see FIG. 4) exemplarily described with reference to FIG. 4 may be understood as including the notch N1 and the notch N2 formed at different locations and is not necessarily limited to the arrangement shown in FIG. 4.

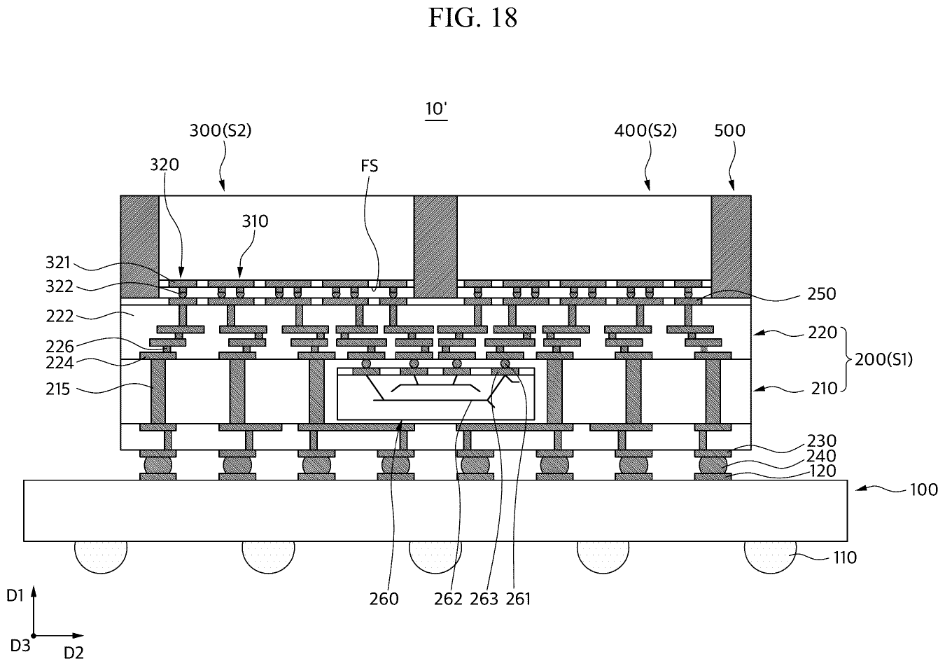

FIG. 18 is a drawing schematically illustrating a semiconductor package according to an embodiment.

Hereinafter, a semiconductor package 10′ according to an embodiment with reference to FIG. 18 is described. The semiconductor package 10′ described below has a structure and function that are mostly identical or similar to the semiconductor package 10 (see FIG. 2) described above, except otherwise described in embodiments.

Referring to FIG. 18, the interposer structure 200 may further include a bridge structure 260. In some embodiments, the bridge structure 260 may be disposed on the front side of the redistribution layer 220. Further, the bridge structure 260 may be disposed within the interposer 210. The bridge structure 260 may be disposed between the first semiconductor chip 300 and the second semiconductor chip 400 (e.g., in the second direction D2). Further, the bridge structure 260 may overlap at least a portion of the first semiconductor chip 300 and at least a portion of the second semiconductor chip 400 in the first direction D1.

In some embodiments, the bridge structure 260 may include a bridge bump 261, a plurality of bridge lines 262, and a bridge pad 263. The bridge bump 261 may be disposed on the front side of the bridge structure 260. The bridge lines 262 may be disposed inside the bridge structure 260. The bridge lines 262 may include a conductive material. In an embodiment, the bridge pad 263 may be disposed on the lower side of the bridge bump 261, and may be electrically connected by making direct contact with the bridge bump 261 and the bridge lines 262. The bridge bump 261 may be electrically connected to redistribution lines (e.g., the redistribution pattern 224 and the redistribution via 226) of the redistribution layer 220 of the interposer structure 200. A portion of the bridge bump 261 may be electrically connected to redistribution lines (e.g., the redistribution pattern 224 and the redistribution via 226) that are electrically connected to the first semiconductor chip 300, and another portion of the bridge bump 261 may be electrically connected to the redistribution lines (e.g., the redistribution pattern 224 and the redistribution via 226) that are electrically connected to the second semiconductor chip 400. The bridge bump 261 may include a conductive material. For example, in an embodiment the bridge bump 261 may contain a solder ball or a solder bump.

The above described embodiments are illustrative of the present disclosure. Further, the foregoing descriptions illustrate and explain non-limiting embodiments of the present disclosure, and the present disclosure may be used in various other combinations, modifications and environments. For example, changes or modifications may be made within the scope of embodiments of the present disclosure described in the present disclosure. Therefore, the described embodiments are not intended to limit the scope of embodiments of the present disclosure.

What is claimed is:

1. A semiconductor package comprising an upper part structure, a lower part structure, and a first connecting body electrically connecting the upper part structure to the lower part structure,
wherein the first connecting body comprises:
a first pad disposed on a front side of the upper part structure; and
a plurality of first bumps disposed on the first pad, the plurality of first bumps is electrically connected to each other via the first pad,
wherein the plurality of first bumps are spaced radially apart from a central area of the first pad.

2. The semiconductor package of claim 1, wherein the first connecting body comprises a notch that is positioned on the central area of the first pad and recessed towards the upper part structure.

3. The semiconductor package of claim 2, further comprising a second connecting body electrically connecting the upper part structure to the lower part structure,
wherein the second connecting body comprises:
a second pad disposed on the front side of the upper part structure; and
a second bump disposed on the second pad,
wherein the second bump and the second pad are arranged to correspond to each other in a one-to-one arrangement.

4. The semiconductor package of claim 3, wherein each of the plurality of first bumps has a cross-sectional area that is identical to a cross-sectional area of the second bump.

5. The semiconductor package of claim 3, wherein a vertical level of a tip of each of the plurality of first bumps and a vertical level of a tip of the second bump are identical to each other based on the front side of the upper part structure.

6. The semiconductor package of claim 3, wherein:
the plurality of first bumps comprises a power bump transmitting a power signal between the upper part structure and the lower part structure, and
the second bump comprises a signal bump transmitting a data signal between the upper part structure and the lower part structure.

7. The semiconductor package of claim 6, wherein:
the front side of the upper part structure comprises a core area including a center of the front side of the upper part structure, and a sub-area that comprises a remaining area of the front side of the upper part structure that does not include the core area, and
a plurality of first connecting bodies are disposed on the core area and a plurality of second connecting bodies are disposed on the sub-area.

8. The semiconductor package of claim 1, wherein the first pad comprises:
a center pad that is disposed on the central area; and
a plurality of edge pads that are disposed along a perimeter of the center pad,
wherein the center pad and the plurality of edge pads are integral with each other.

9. The semiconductor package of claim 8, wherein the plurality of first bumps are solely disposed on the plurality of edge pads.

10. The semiconductor package of claim 9, wherein each of the plurality of first bumps comprises a pillar and a micro bump that is disposed on a front side of the pillar,
wherein the upper part structure comprises:
a passivation layer exposing at least a portion of the center pad and covering a front side of the plurality of edge pads, the passivation layer comprises an opening part exposing at least a portion of the plurality of edge pads; and
an under bump metallization (UBM) layer disposed between the pillar and the edge pad to fill the opening part, the UBM layer electrically connecting the pillar and the edge pad to each other.

11. The semiconductor package of claim 1, wherein the upper part structure and the lower part structure comprise at least one of a semiconductor chip, an interposer, a package substrate, a redistribution substrate and an external circuit substrate.

12. The semiconductor package of claim 2, wherein the notch is an energy dispersive X-ray spectroscopy (EDS) measurement point of the first pad and the plurality of first bumps electrically connected to the first pad.

13. The semiconductor package of claim 1, wherein the plurality of first bumps comprises a solder ball,
wherein the solder ball is electrically connected to the first pad through a layer containing a conductive material.

14. A semiconductor package comprising a semiconductor device and a connecting body that is disposed on a side of the semiconductor device,
wherein the connecting body comprises:
a center pad electrically connected to the semiconductor device;
a plurality of edge pads electrically connected to the semiconductor device and the center pad, the plurality of edge pads are spaced apart from each other and surround the center pad; and
a plurality of bumps disposed on the plurality of edge pads,
wherein the center pad has one side that is exposed to an outside of the semiconductor device.

15. The semiconductor package of claim 14, wherein the plurality of edge pads are spaced apart from each other at equal intervals based on a center of the center pad.

16. The semiconductor package of claim 15, wherein:
the semiconductor device comprises a passivation layer exposing at least a portion of the center pad and covering the plurality of edge pads, the passivation layer comprises an opening part exposing at least a portion of the plurality of edge pads; and
each of the plurality of bumps is disposed on the opening part and is electrically connected to the plurality of edge pads.

17. The semiconductor package of claim 14, wherein the connecting body further comprises a notch disposed on the one side of the center pad exposed to the outside of the semiconductor device.

18. The semiconductor package of claim 14, wherein the plurality of bumps includes a power bump transmitting a power signal.

19. A semiconductor package comprising:
an interposer structure including a through via disposed inside the interposer structure;
a semiconductor chip disposed on the interposer structure; and
a first connecting body and a second connecting body disposed on a front side of the semiconductor chip facing the interposer structure, the first connecting body and the second connecting body electrically connecting the semiconductor chip and the interposer structure to each other,
wherein the first connecting body comprises:
a first pad disposed inside the semiconductor chip and electrically connected to distribution lines that transmit power signals of the semiconductor chip; and
a power bump disposed on the front side of the semiconductor chip, the power bump is electrically connected to the first pad,
wherein the second connecting body comprises:
a second pad disposed inside the semiconductor chip and electrically connected to distribution lines transmitting data signals of the semiconductor chip; and
a signal bump disposed on the front side of the semiconductor chip, the signal bump is electrically connected to the second pad,
wherein, the semiconductor chip includes a first area and a second area surrounding the first area, the power bump is disposed on the first area and the signal bump is disposed on the second area,
wherein a plurality of power bumps are disposed on the first pad, and
wherein the signal bump is disposed on the second pad.

20. The semiconductor package of claim 19, wherein the first pad comprises:
a center pad disposed in a central area of the first pad; and
a plurality of edge pads that are spaced radially apart and surround the center pad,
wherein each of the plurality of power bumps is solely disposed on each the plurality of edge pads.
